(19) United States
(12) Patent Application Publication
(10) Pub. No.: US 2024/0172371 A1
(43) Pub. Date: May 23, 2024

(54) SEMICONDUCTOR PACKAGES AND METHOD FOR FABRICATING THE SAME

(71) Applicant: Samsung Electronics Co., Ltd., Suwon-si (KR)

(72) Inventors: JIHYUN LEE, Suwon-si (KR); HANSUNG RYU, Suwon-si (KR); YONG SUNG PARK, Suwon-si (KR); JUNHO LEE, Suwon-si (KR)

(21) Appl. No.: 18/226,568

(22) Filed: Jul. 26, 2023

(30) Foreign Application Priority Data
Nov. 18, 2022 (KR) 10-2022-0155475

(51) Int. Cl. H05K 3/34; H01L 21/48; H01L 23/498; H01L 23/522

(52) U.S. Cl. CPC H05K 3/3463; H01L 21/4853; H01L 23/49816; H01L 23/5226

(57) ABSTRACT

A semiconductor package includes a first structure, a second structure, a plurality of first connection members including SnBi; a plurality of second connection members including SAC (Sn, Ag and Cu). Each first connection member of the plurality of first connection members has a first surface and a second surface opposite each other, and the first surface of each first connection member of the plurality of first connection members is bonded to the first structure. A third surface of each second connection member of a plurality of second connection members is bonded to a corresponding second surface of a respective first connection member, and for each second connection member, a fourth surface of the second connection member that is opposite the third surface of the second connection member is bonded to the second structure. The third surface of each second connection member is flat, and a diameter of each second connection member decreases in a direction receding from the third surface of each second connection member.

### CROSS-REFERENCE TO RELATED APPLICATION

This application claims priority under 35 U.S.C. § 119 to and the benefit of Korean Patent Application No. 10-2022-0155475 filed in the Korean Intellectual Property Office on Nov. 18, 2022, the entire contents of which are incorporated herein by reference.

### BACKGROUND

### (a) Field of the Invention

The present invention relates to a semiconductor package and a manufacturing method thereof.

### (b) Description of the Related Art

In the semiconductor industry, in a process of bonding a semiconductor chip package and Printed Circuit Board (PCB), a use of lead (Pb) is decreasing and a use of tin (Sn) is increasing as an alternative material to lead (Pb) to reduce an effect of lead (Pb) on the environment. However, since the bonding process based on tin instead of lead is performed at a high temperature, more energy is consumed and parts are easily deteriorated. Therefore, in order to address this problem, the need for a bonding process technology that can be performed at a lower temperature has increased, and as such a bonding process technology, a surface Mount Technology (SMT) with which a semiconductor chip package is bonded to a printed circuit board (PCB) by applying SAC solder balls, which are a mixture of tin (Sn), silver (Ag) and copper (Cu), to the semiconductor chip package, and applying a low temperature soldering (LTS) paste to the printed circuit board (PCB) has been developed.

When applying this low temperature soldering paste to the surface mounting technology (SMT) bonding the semiconductor chip package and the printed circuit board (PCB) to each other, compared to a high temperature process, cost is reduced, and warpage of final semiconductor packages is reduced, and defects of the devices are reduced. Therefore, based on these advantages, a low temperature soldering paste using a Sn—Bi (tin-bismuth)-based material is being used as one of the important materials for the surface mounting technology (SMT).

However, in the case of the low temperature soldering paste using Sn—Bi-based materials, when the surface mounting technology (SMT) is performed, Bi in the low temperature soldering paste diffuses to the edge of the SAC solder ball of the semiconductor chip package, so it may ride up to the metal pad of the semiconductor chip package. This causes a crack at the interface between the metal pad of the semiconductor chip package and the SAC solder ball (Inter Metallic Compound (IMC)), in a board level reliability evaluation (BLR) conducted after the surface mounting technology (SMT) is performed, it becomes a factor that causes the reliability to deteriorate.

Therefore, it will be helpful to develop a new package technology that may prevent the Bi included in the low temperature soldering paste from rising to the edge of the SAC solder ball and being diffused into the semiconductor chip package.

### SUMMARY

Embodiments provide a semiconductor package and a semiconductor package manufacturing method in which connection members connected to a semiconductor chip package have a flat bottom surface and a side surface whose diameter decreases in a direction receding from a bottom toward a top of the connection members in order to prevent Bi in the low temperature soldering paste from rising to the edge of the SAC solder ball and being diffused into the semiconductor chip package when performing the surface mounting technology (SMT), and in order to improve a reliability in a board level reliability evaluation performed after performing the surface mounting technology (SMT).

An embodiment, in order to address the above-mentioned problems, in addition to the fact that the connection members connected to the semiconductor chip package have the flat bottom surface and the side surface whose diameter decreases in a direction receding from the bottom toward the top, provides a semiconductor package and a semiconductor package manufacturing method in which an under-bump structure is formed between the connection members and the metal pad of the semiconductor chip package.

An embodiment, in order to address the above-mentioned problems, in addition to the fact that the connection members connected to the semiconductor chip package have the flat bottom surface and the side surface whose diameter decreases in a direction receding from the bottom toward the top, provides a semiconductor package and a semiconductor package manufacturing method in which an oxide layer is formed on the side of the connection members.

An embodiment, in order to address the above-mentioned problems, in addition to the fact that the connection members connected to the semiconductor chip package have the flat bottom surface and the side surface whose diameter decreases in a direction receding from the bottom toward the top, provides a semiconductor package and a semiconductor package manufacturing method in which a barrier layer is formed on the bottom surface and the side of the connection members.

According to some embodiments, a semiconductor package includes a first structure, a second structure, a plurality of first connection members including SnBi; a plurality of second connection members including SAC (Sn, Ag and Cu). Each first connection member of the plurality of first connection members has a first surface and a second surface opposite each other, and the first surface of each first connection member of the plurality of first connection members is bonded to the first structure. A third surface of each second connection member of a plurality of second connection members is bonded to a corresponding second surface of a respective first connection member, and for each second connection member, a fourth surface of the second connection member that is opposite the third surface of the second connection member is bonded to the second structure. The third surface of each second connection member is flat, and a diameter of each second connection member decreases in a direction receding from the third surface of each second connection member.

According to some embodiments, a semiconductor package includes a first structure, a second structure, a plurality of first connection members, and a plurality of second connection members. The first structure includes a plurality of first vias, a plurality of first metal pads on the plurality of first vias, a first insulation layer surrounding the plurality of first vias, and a second insulation layer disposed on the first insulation layer and including a plurality of openings. The second structure includes a third insulation layer, a plurality of second metal pads on the third insulation layer, a plurality of second vias on the plurality of second metal pads, and a fourth insulation layer surrounding the plurality of second metal pads and the plurality of second vias. The plurality of first connection members include SnBi, and the plurality of second connection members include SAC (Sn, Ag and Cu). A first surface of each first connection member of the plurality of first connection members is bonded to a corresponding first metal pad of the plurality of first metal pads through a corresponding opening of the plurality of openings; each second connection member of the plurality of second connection members penetrates the third insulation layer, for each first connection member, a second surface of the first connection member opposite the first surface of the first connection member is bonded to a third surface of a corresponding one of the plurality of second connection members, and for each second connection member of the plurality of second connection members, a fourth surface opposite the third surface of the is bonded to a corresponding second metal pad of the plurality of second metal pads; the third surface of each second connection member of the plurality of second connection members is flat, and a diameter in a horizontal direction of each second connection member of the plurality of second connection members decreases in a direction receding from the third surface.

According to some embodiments, a semiconductor package manufacturing method includes forming a first package including a plurality of connection members including SAC (Sn, Ag and Cu); pressing the first package to coin the plurality of connection members, wherein each coined connection member of the plurality of coined connection members has a diameter in a horizontal direction decreasing in a direction receding from a bottom of the connection member; forming a second package including a plurality of soldering pastes including SnBi; and bonding the plurality of coined connection members and the plurality of soldering pastes respectively under a predetermined temperature.

According to an embodiment, since the connection members connected to the semiconductor chip package have the flat bottom surface and the side surface whose diameter decreases from bottom to top, it is possible to prevent the low temperature soldering paste including Bi from flowing to the edge of the connection member, and thus to prevent the connection members after the thermal treatment from having a brittleness due to the Bi diffusion and having a brittle property.

According to an embodiment, due to the shape of the connection member of the proposed semiconductor package, the cracks may be prevented from being formed at the interface between the metal pad and the connection member in the semiconductor chip package, and in a board level reliability evaluation after performing a surface mounting technology (SMT), a reliability level may be improved.

According to an embodiment, since a proper angle is created between the bottom surface and the side surface of the connection members due to the shape of the connection member of the proposed semiconductor package, the flow of the low temperature soldering paste in the upper direction (toward the semiconductor chip package) may be controlled, and the low temperature soldering paste that does not flow in the upper direction may be flowed in the lower direction (toward the printed circuit board (PCB)) instead, thereby the upper and side surfaces of the metal pad in the printed circuit board PCB may be wetted with the low temperature soldering paste.

### BRIEF DESCRIPTION OF THE DRAWINGS

FIG. 1 is a cross-sectional view showing that SAC solder balls under a semiconductor chip package and low temperature soldering pastes on a printed circuit board (PCB) are aligned before a bonding in a conventional semiconductor package.

FIG. 2 is a cross-sectional view showing that SAC solder balls under a semiconductor chip package and connection members on a printed circuit board (PCB) are boned to each other in a conventional semiconductor package.

FIG. 3 is a photograph showing that Bi in a low temperature soldering paste diffuses into a SAC solder ball to form an interface layer in a conventional semiconductor package.

FIG. 4 is a photograph showing a crack formed between a metal pad of a semiconductor chip package and a SAC solder ball in a conventional semiconductor package.

FIG. 5 is a picture showing a distance between a maximum height of Bi and a metal pad of a semiconductor chip package, which may be evaluated as improving a reliability in a board level reliability evaluation of an embodiment.

FIG. 6 is a cross-sectional view of a semiconductor package showing an entire structure of a printed circuit board (PCB), connection members, coined connection members and a semiconductor chip package according to an embodiment.

FIG. 7 is a cross-sectional view showing a semiconductor package in which coined connection members under a semiconductor chip package and connection members on a printed circuit board (PCB) are bonded to each other according to an embodiment.

FIG. 8 is a cross-sectional view showing a semiconductor package including an under-bump structure disposed between coined connection members and a semiconductor chip package according to an embodiment.

FIG. 9 is a cross-sectional view showing a semiconductor package including an oxide layer formed on a side surface of coined connection members according to an embodiment.

FIG. 10 is a cross-sectional view showing a semiconductor package including a barrier layer formed on a bottom surface and a side surface of coined connection members according to an embodiment.

FIG. 11 is a cross-sectional view showing a step of forming a connection member (a solder ball) on a semiconductor chip package as one among steps of a semiconductor package manufacturing method according to an embodiment.

FIG. 12 is a cross-sectional view showing a step of preparing to coin a connection member (a solder ball) to a semiconductor chip package as one among steps of a semiconductor package manufacturing method according to an embodiment.

FIG. 13 is a cross-sectional view showing a step of forming a coined connection member by coining a connection member (a solder ball) to a semiconductor chip package as one among steps of a semiconductor package manufacturing method according to an embodiment.

FIG. 14 is a cross-sectional view showing a step of completing a coined connection member as one among steps of a semiconductor package manufacturing method according to an embodiment.

FIG. 15 is a cross-sectional view showing a step of aligning coined connection members under a semiconductor chip package and low temperature soldering pastes on a printed circuit board (PCB) as one among steps of a semiconductor package manufacturing method of an embodiment.

FIG. 16 is a cross-sectional view showing a step of forming a semiconductor package by bonding coined connection members under a semiconductor chip package and low temperature soldering pastes on a printed circuit board (PCB) as one among steps of a semiconductor package manufacturing method according to an embodiment.

### DETAILED DESCRIPTION OF THE EMBODIMENTS

Hereinafter, an exemplary embodiment of the present invention will be described more fully with reference to the accompanying drawings for a person of ordinary skill to easily implement the present invention. As those skilled in the art would realize, the described embodiments may be modified in various different ways, all without departing from the spirit or scope of the present invention.

The drawings and descriptions are to be regarded as illustrative in nature and not restrictive. Like reference numerals designate like elements throughout the specification.

Because the size and thickness of each configuration shown in the drawings are arbitrarily shown for better understanding and ease of description, the present invention is not limited thereto.

Throughout the specification, when it is described that a part is “coupled” to another part, the part may be “directly or physically connected” to the other part or “indirectly or non-contact coupled” to the other part with a third part therebetween. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. For example, spatially relative terms, such as “beneath,” “below,” “lower,” “above,” “upper” and the like, may be used herein for ease of description to describe positional relationships, such as illustrated in the figures. It will be understood that the spatially relative terms encompass different orientations of the device in addition to the orientation depicted in the figures.

Further, in the specification, the phrase “on a plane” means when an object portion is viewed from above, and the phrase “on a cross-section” means when a cross-section taken by vertically cutting an object portion is viewed from the side.

Hereinafter, a semiconductor package of an embodiment will be described with reference to drawings.

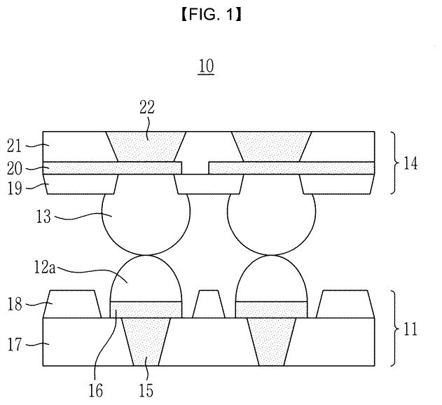

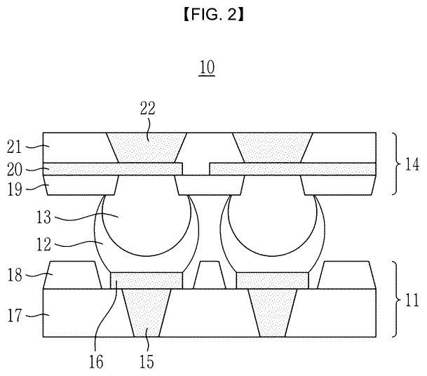

FIG. 1 and FIG. 2 show a conventional semiconductor package 10 for a low temperature junction. In FIG. 1 and FIG. 2, for convenience, only components adjacent to SAC solder balls 13 in a semiconductor chip package 14 and components adjacent to low temperature soldering pastes 12a in a printed circuit board 11 are shown, and some components are omitted.

As a lead-free solder to replace lead, a SAC solder alloy including tin (Sn), silver (Ag) and copper (Cu) is used. The SAC solder alloy has a melting start temperature of about 217° and a bonding temperature of about 250° C. to 260° C. For example, the melting start temperature of the SAC solder alloy may be a temperature at which the SAC solder alloy starts to melt when temperature is increased from a lower temperature than the melting start temperature, e.g., room temperature. The SAC solder alloy may melt better at a higher temperature, and the bonding temperature of the SAC solder alloy may be a temperature at which the SAC solder bonding process is performed. Therefore, when performing the bonding process with the SAC solder alloy, since high temperature is essential, more energy is consumed, a warpage of the semiconductor package increases, and elements that are greatly affected by temperature are greatly affected. To solve these problems, the SAC solder balls 13 may be used as a connection member connected to the semiconductor chip package 14, and low temperature soldering pastes 12a capable of low temperature junction may be used as a connection member connected to the printed circuit board 11.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

FIG. 1 is a cross-sectional view that SAC solder balls 13 under a semiconductor chip package 14 and low temperature soldering pastes 12a on a printed circuit board 11 are aligned with (e.g., vertically overlap) each other before bonding in a conventional semiconductor package 10.

Referring to FIG. 1, the semiconductor package 10 may include a printed circuit board 11, low temperature soldering pastes 12a, SAC solder balls 13 and a semiconductor chip package 14 as a configuration/arrangement before bonding. The low temperature soldering pastes 12a may be disposed on the printed circuit board 11, and the SAC solder balls 13 may be disposed under the semiconductor chip package 14. For example, the SAC solder balls 13 may be disposed on a bottom surface of the semiconductor chip package 14.

The printed circuit board 11 may include vias 15, metal pads 16 on the vias 15, an insulation layer 17 surrounding the vias 15, and an isolation insulation layer 18 on the insulation layer 17.

The low temperature soldering pastes 12a may be bonded to be electrically coupled with the metal pads 16 of the printed circuit board 11. Since it is before a reflow process, the low temperature soldering pastes 12a have a state before melting.

As used herein, items described as being “electrically connected” or “electrically coupled” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component.

The SAC solder balls 13 may be aligned facing the low temperature soldering pastes 12a. The SAC solder balls 13 may be bonded to be electrically coupled to the metal pads 20 of the semiconductor chip package 14.

The semiconductor chip package 14 may include metal pads 20, vias 22 on metal pads 20, an insulation layer 21 surrounding the metal pads 20 and the vias 22, and an isolation insulation layer 19 disposed under the metal pads 20 and the insulation layer 21.

FIG. 2 is a cross-sectional view that a SAC solder ball 13 under a semiconductor chip package 14 and a connection member 12 on a printed circuit board 11 are bonded to each other in a conventional semiconductor package 10.

Referring to FIG. 2, the low temperature soldering paste 12a may include SnBi. The SAC solder balls 13 may include tin (Sn), silver (Ag) and copper (Cu). The temperature at which the melting of the SAC begins is about 217° C., and the temperature at which the melting of SnBi begins is about 139° C., however to improve the reliability of the bonding, the bonding process may be performed at a temperature of about 190° C. When heat treatment is performed at a temperature of about 190° C., the SAC solder ball 13 whose melting start temperature is about 217° C. does not melt and only the low temperature soldering paste 12a whose melting start temperature is about 139° C. melts. When the molten low temperature soldering paste 12a flows along the SAC solder ball 13 and the low temperature soldering paste 12a hardens after the heat treatment, the bonding is performed between the low temperature soldering paste 12a and the SAC solder ball 13. After the heat treatment, the low temperature soldering paste 12a is cured and becomes the connection member 12.

Since the SAC solder ball 13 has a ball shape, the low temperature soldering paste 12a may flow along the surface of the ball shape of the SAC solder ball 13 and reach the boundary between the SAC solder ball 13 and the semiconductor chip package 14. Also, Bi included in the low temperature soldering paste 12a diffuses into the SAC solder ball 13, and Bi in the low temperature soldering paste 12a reaching the boundary between the SAC solder ball 13 and the semiconductor chip package 14 may diffuse to the semiconductor chip package 14 via the SAC solder ball 13 and/or along the edge of the SAC solder ball 13.

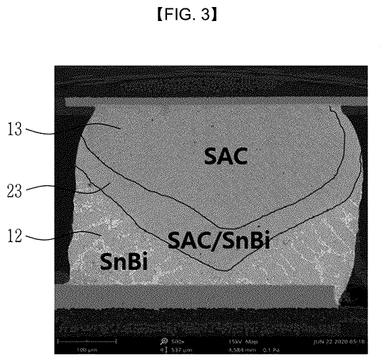

FIG. 3 is a photograph showing that Bi in the low temperature soldering paste 12a diffuses into the SAC solder ball 13 to form the interface layer 23 in a conventional semiconductor package.

Referring to FIG. 3, Bi is diffused so that the interface layer 23 may be formed between the SAC solder ball 13 and the connection member 12. The interface layer 23 may include both SAC and SnBi. SAC and SnBi may each have a concentration gradient in the thickness direction from the SAC solder ball 13 to the connection member 12 within the interface layer 23. The diffusion speed of Bi is faster at the edge of the SAC solder ball 13 closer to the semiconductor chip package 14 than in the middle of the interface layer 23 between the SAC solder ball 13 and the low temperature soldering paste 12a.

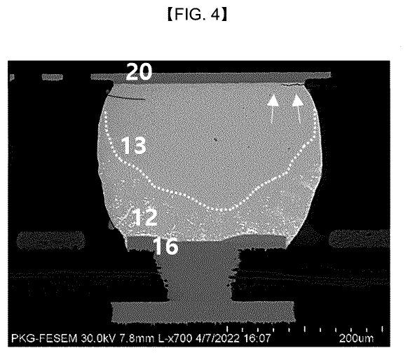

FIG. 4 is a photograph showing a crack formed between a metal pad 20 of a semiconductor chip package 14 and a SAC solder ball 13 in a conventional semiconductor package.

SnBi is a low temperature junction material, but the Bi component has brittleness, making it vulnerable to a drop impact and a thermal deformation. Therefore, due to Bi diffused to the boundary between the SAC solder ball 13 and the semiconductor chip package 14, a crack (indicated by arrows) may be formed between the metal pad 20 of the semiconductor chip package 14 and the SAC solder ball 13. The generation of such cracks causes deterioration of reliability in the board level reliability evaluation (BLR) that is performed after the surface mounting technology (SMT) is performed.

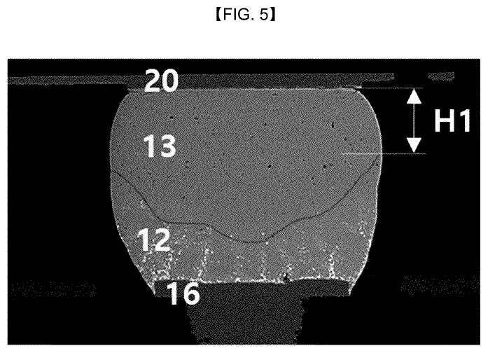

FIG. 5 is a photograph showing a distance H1 between a maximum height (e.g., the highest position) of Bi and a metal pad 20 of a semiconductor chip package 14, which may be evaluated as improving a reliability in a board level reliability evaluation (BLR) of an embodiment.

One of the board level reliability evaluation (BLR) is a drop reliability evaluation. The following is a result value of a cumulative inferiority rate of 10% derived/obtained by performing the drop reliability evaluation. For example, the cumulative inferiority rate may be a cumulative fail rate in a test/evaluation.

In a case that the distance H1 between the highest position (maximum height) of Bi on the edge of the SAC solder ball 13 and the metal pad 20 of the semiconductor chip package 14 is 30% or more of the distance between the metal pad 20 of the semiconductor chip package 14 and the metal pad 16 of the printed circuit board 11, the cumulative inferiority rate of 10% of the result value was derived with 584 drops of the semiconductor package.

In a case that the distance H1 between the highest position (maximum height) of Bi on the edge of the SAC solder ball 13 and the metal pad 20 of the semiconductor chip package 14 is less than 30% of the distance between the metal pad 20 of the semiconductor chip package 14 and the metal pad 16 of the printed circuit board 11, the cumulative inferiority rate of 10% of the result value was derived with 129 drops of the semiconductor package

According to this test result, from the fact that the cumulative inferiority rate of 10% is derived only when more drops should be performed, in the case that the distance H1 is 30% or more of the distance between the metal pad 20 of the semiconductor chip package 14 and the metal pad 16 of the printed circuit board 11, it may be seen that there is a greater drop reliability of the semiconductor package than the case that the distance between the metal pad 20 of the semiconductor chip package 14 and the metal pad 16 of the printed circuit board 11 is less than 30%. Therefore, if the semiconductor package structure is designed so that Bi is diffused to a position of which distance from the metal pad 20 of the semiconductor chip package 14 is 30% or more of the distance between the metal pad 20 of the semiconductor chip package 14 and the metal pad 16 of the printed circuit board 11, there may be a great improvement in the drop reliability evaluation.

Another board level reliability evaluation (BLR) is a thermal cycle test (TC). As a result of the thermal cycle test (TC), when (a volume of the low temperature soldering paste 12a)/(a volume of the SAC solder ball 13) was 0.4 to 0.5, the result of the thermal cycle test (TC) was the best. Therefore, it will be helpful to design the semiconductor package structure so that a ratio of the volume of the low temperature soldering paste 12a of the printed circuit board 11 to the volume of the SAC solder ball 13 of the semiconductor chip package 14 is 0.4 to 1 to 0.5 to 1. For example, a ratio of the volume of the low temperature soldering paste 12a to the volume of the SAC solder ball 13 may be from 0.4 to 0.5 (e.g., between 0.4 and 0.5) in certain embodiments.

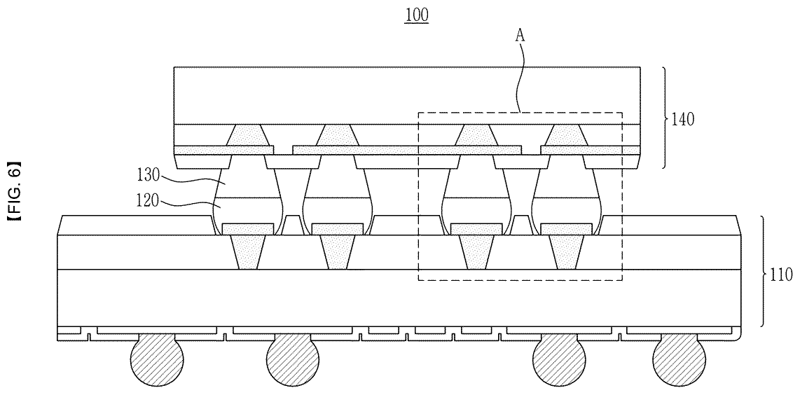

FIG. 6 is a cross-sectional view of a semiconductor package including a printed circuit board 110, first connection members 120, coined second connection members 130 and a semiconductor chip package 140 according to an embodiment.

Referring to FIG. 6, the semiconductor package 100 may include the printed circuit board 110, the first connection members 120 bonded to the printed circuit board 110, the coined second connection members 130 bonded to the first connection members 120, and the semiconductor chip package 140 bonded to the coined second connection members 130.

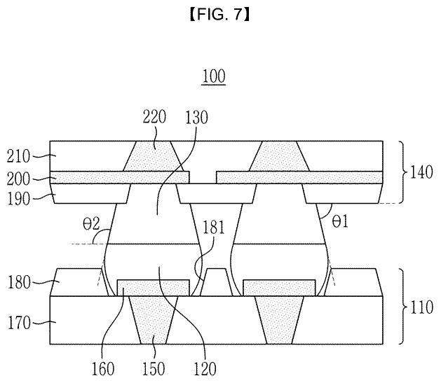

FIG. 7 to FIG. 10 are the cross-sectional views showing the semiconductor packages 100 according to the various embodiments to improve reliability, e.g., in the board level reliability evaluation (BLR). FIG. 7 to FIG. 10 are the enlarged views of the region A of FIG. 6, and for convenience, only components adjacent to the second connection members 130 in the semiconductor chip package 140 and components adjacent to the low temperature soldering pastes 120a in the printed circuit board 110 are shown, and some components are omitted. For example, the omitted components may be the same as one or more of other embodiments or may be the same as the ones of known art. The low temperature soldering paste 120a forms the first connection members 120 in the package 100.

FIG. 7 is the cross-sectional view showing the semiconductor package in which the coined connection members 130 under the semiconductor chip package 140 and the first connection members 120 on the printed circuit board 110 are bonded to each other according to an embodiment.

Referring to FIG. 7, the semiconductor package 100 may include the printed circuit board 110, a plurality of first connection members 120, a plurality of second connection members 130 and the semiconductor chip package 140.

The printed circuit board 110 may include a plurality of first vias 150, a first insulation layer 170 surrounding the plurality of first vias 150, a plurality of first metal pads 160 on the plurality of first vias 150, and a second insulation layer 180 disposed on the first insulation layer 170 and including a plurality of openings 181.

The plurality of first vias 150 may be disposed to pass through the first insulation layer 170. In an embodiment, the plurality of first vias 150 may be formed of a pure copper, a copper-containing composition or a copper alloy. As another embodiment, the plurality of first vias 150 may be formed from other materials such as nickel, aluminum, titanium and their alloys. In an embodiment, the plurality of first vias 150 may be deposited with an electroless plating and an electroplating. In another embodiment, the plurality of first vias 150 may be formed by a physical vapor deposition (PVD). The plurality of first vias 150 may be formed by a sputtering in certain embodiments. In example embodiments, the plurality of first vias 150 are electrically coupled to the plurality of first metal pads 160.

The first insulation layer 170 may be disposed to surround the plurality of first vias 150. For example, the plurality of first visa 150 may penetrate the first insulation layer 170. In an embodiment, the first insulation layer 170 may be a solder resist.

Each first metal pad of the plurality of first metal pads 160 may be disposed on each of the plurality of first vias 150. In an embodiment, the plurality of first metal pads 160 may include or be formed of a copper layer. In an embodiment, the plurality of first metal pads 160 may have a nickel layer or a gold layer formed on a copper layer. In an embodiment, the plurality of first metal pads 160 may include at least one of: copper, aluminum, tungsten, nickel, gold, tin, titanium and alloys thereof. The plurality of first metal pads 160 may electrically couple a plurality of first vias 150 and the first connection members 120.

The second insulation layer 180 may be disposed on the first insulation layer 170. In an embodiment, the second insulation layer 180 may be a solder resist. The second insulation layer 180 may include a plurality of openings 181. Each first metal pad of the plurality of first metal pads 160 may be disposed within a corresponding opening of the plurality of openings 181 of the second insulation layer 180 and may be spaced apart from an inner surface of the opening. For example, the plurality of first metal pads 160 may not contact the second insulation layer 180.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

Each first connection member of the plurality of first connection members 120 may be positioned on a corresponding first metal pad of the plurality of first metal pads 160 of the printed circuit board 110. In an embodiment, the first connection members 120 may include or be formed of SnBi. In an embodiment, the first connection members 120 may be formed by a screen printing method.

Each second connection member of the plurality of second connection members 130 may be bonded onto a corresponding first connection member of the plurality of first connection members 120. In an embodiment, the second connection members 130 may include or be formed of Sn, Ag and Cu (SAC).

The second connection members 130 may include a flat bottom surface and a side surface whose diameter decreases from bottom to top. For example, each of the second connection members 130 has a circular cross-section in a horizontal plane crossing the second connection members 130, has a diameter in a horizontal direction, and the diameter of each second connection member 130 decreases in a direction receding from its bottom surface toward its top surface. As an embodiment, the second connection members 130 may include/have a truncated circular cone shape. The shape of the bottom surface of the second connection members 130, which is flat and has a wider area than the upper surface, allows the molten low temperature soldering paste 120a to flow only on the flat bottom surface of the second connection member 130 during heat treatment, and the molten low temperature soldering paste 120a may be prevented from flowing along the side surface of the second connection member 130 and reaching the boundary of the semiconductor chip package 140. In certain cases, the soldering paste 120a may flow on a lower area of the side surface of the second connection member 130. However, the soldering paste 120a may not flow on an upper area of the side surface of the second connection member 130 because the flat bottom surface of the of the second connection member 130 makes it difficult for the soldering paste 120a to flow onto the side surface of the second connection member 130. Therefore, crack may be prevented from being formed between semiconductor chip package 140 and second connection members 130, and board level reliability evaluation (BLR) may be improved.

In addition, due to the shape of the bottom surfaces of the second connection members 130, which is flat and has the wider area than the upper surface, the molten low temperature soldering paste 120a that is prevented from flowing upward (toward the semiconductor chip package 140) along the side surface of the second connection member 130 may flow downward (toward the printed circuit board 110). The low temperature soldering paste 120a flowing downward wets the upper and side surfaces of the first metal pad 160, and this improves reliability, e.g., in the board level reliability evaluation (BLR). For example, the low temperature soldering paste 120a may surround and/or contact the upper and side surfaces of the first metal pad 160.

An angle θ1 between the bottom surface of the semiconductor chip package 140 and the side surface of the second connection member 130 may be 60° to 80°. When the angle θ1 between the bottom surface of the semiconductor chip package 140 and the side surface of the second connection member 130 is lower than 60°, the side surface is excessively tilted and the second connection members 130 are bonded with each other, which may cause a circuit short circuit. When the angle θ1 between the bottom surface of the semiconductor chip package 140 and the side surface of the second connection member 130 is higher than 60°, it is difficult to prevent that the molten low temperature soldering paste 120a flows along the side surface of the second connection member and reaches the boundary of the semiconductor chip package 140. The angle (a contact angle; θ2) between the interface of the first connection member 120 and the second connection member 130 and the side surface of the second connection member 130 may be 100° to 120°. For example, the contact angle (θ2) may be an angle between a side surface of the second connection member 130 and an extension line of the interface between the first connection member 120 and the second connection member 130 extending outside the first connection member 120 and the second connection member 130 in a vertical cross-section as shown in FIG. 7.

To improve reliability in the board level reliability evaluation (BLR), a volume ratio of the first connection member 120 to the second connection member 130 may be 0.4:1 to 0.5:1.

The first connection member may include or be formed of SnBi with a melting point of about 139° C. and the second connection member may include or be formed of SAC with a melting point of about 217 C.

An interface layer (not shown) formed by the diffusion may be included between the first connection member 120 and the second connection member 130. As an embodiment, the interface layer may include or be formed of both SnBi and SAC.

The semiconductor chip package 140 may include a third insulation layer 190, a plurality of second metal pads 200 on the third insulation layer 190, a plurality of second metal vias 220 on the plurality of second metal pads 200, and a fourth insulation layer 210 surrounding the plurality of second metal pads 200 and the plurality of second metal vias 220. As an embodiment, the semiconductor chip of the semiconductor chip package 140 may include or may be a memory chip such as DRAM, SRAM, and the like. The semiconductor chip package 140 may include or may be a BGA package or a flip chip package. As another embodiment, semiconductor chips such as non-memory chips or memory chips, single chips or multi-chips and other semiconductor chip packages, are included in the scope of the present disclosure. For example, the semiconductor chip of the semiconductor chip package 140 may be one of non-memory chips, memory chips, single chips and multi-chips.

The third insulation layer 190 is disposed to prevent a short circuit between the second connection members 130. In an embodiment, the third insulation layer 190 may be a solder resist. The third insulation layer 190 may be penetrated by a plurality of second connection members 130. The third insulation layer 190 may be in contact with the second connection members 130.

The plurality of second metal pads 200 may be disposed on the third insulation layer 190. In an embodiment, the plurality of second metal pads 200 may include or be formed of at least one of: copper, aluminum, tungsten, nickel, gold, tin, titanium and alloys thereof. The plurality of second metal pads 200 may electrically couple the second connection members 130 and the plurality of second vias 220.

The fourth insulation layer 210 may be disposed to surround the plurality of second metal pads 200 and the plurality of second metal vias 220. In an embodiment, the fourth insulation layer 210 may be formed of a polymer such as PBO and/or polyimide. In another embodiment, the fourth insulation layer 210 may be formed of an inorganic dielectric material such as silicon nitride and/or silicon oxide.

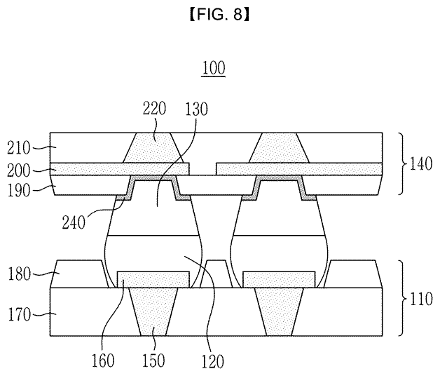

FIG. 8 is a cross-sectional view showing a semiconductor package including an under-bump structure 240 disposed between a coined second connection member 130 and a semiconductor chip package 140 according to an embodiment.

Referring to FIG. 8, the semiconductor package 100 may include the under-bump structure 240 disposed between the coined second connection member 130 and the semiconductor chip package 140. Even if the low temperature soldering paste 120a melted during heat treatment flows along the side surface of the second connection member 130 and reaches the boundary of the semiconductor chip package 140, the under-bump structure 240 serves as a barrier to prevent Bi from being in contact with the semiconductor chip package 140 by the diffusion, thereby preventing cracks from being generated. In addition, the under-bump structure 240 may increase the distance between the coined second connection member 130 and the second metal pad 200 by the thickness of the under-bump structure 240. As an embodiment, the under-bump structure 240 may include or be formed of titanium, titanium alloy and titanium compound. As an embodiment, the under-bump structure 240 may be formed by electrolytic or electroless plating. As another embodiment, the under-bump structure 240 may be formed by a suitable metal deposition operation/process, e.g., a physical vapor deposition (PVD) (e.g., a sputtering), a chemical vapor deposition (CVD) and/or an atomic layer deposition (ALD).

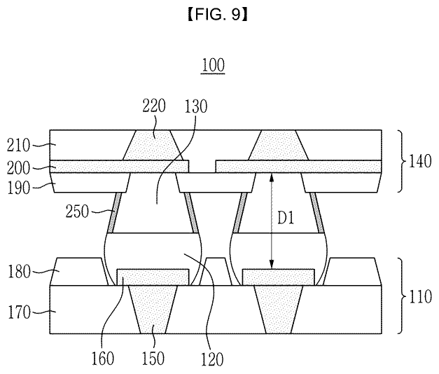

FIG. 9 is a cross-sectional view showing a semiconductor package 100 including an oxide layer 250 formed on a side surface of a coined second connection member 130 according to an embodiment.

Referring to FIG. 9, the semiconductor package 100 may include an oxide layer 250 on the side surface of the second connection member 130. Even if the low temperature soldering paste 120a melted during heat treatment flows along the side surface of the oxide layer 250, the oxide layer 250 acts as a barrier to prevent Bi from being in contact with the semiconductor chip package 140 by the diffusion and cracks may be prevented from being generated. As an embodiment, the oxide layer 250 may include at least one of: Sn oxide, Ag oxide and Cu oxide. As an embodiment, the thickness of the oxide layer 250 may be about 10 nm. As an embodiment, the oxide layer 250 may have a height equal to or greater than 30% of the sum of the heights of the first connection member 120 and the second connection member 130. As an embodiment, the lowermost level of the oxide layer 250 may be positioned lower than a height of 70% of the distance D1 between the first metal pad 160 and the second metal pad 200 from the first metal pad 160.

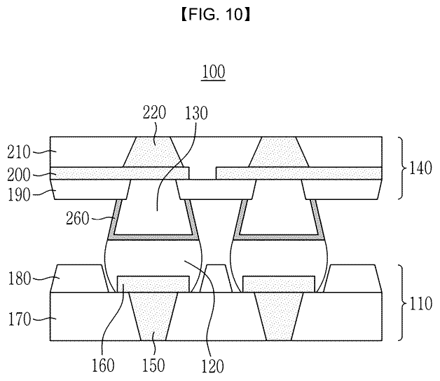

FIG. 10 is a cross-sectional view showing a semiconductor package 100 including a barrier layer 260 formed on a bottom surface and a side surface of coined second connection members 130 according to an embodiment.

Referring to FIG. 10, the semiconductor package 100 may include the barrier layer 260 surrounding the bottom surface and the side surface of the second connection member 130. For example, the barrier layer 260 may be formed to contact the bottom surface and the side surface of the second connection member 130. Even if the low temperature soldering paste 120a melted during heat treatment flows along the side surface of the barrier layer 260, the barrier layer 260 acts as a barrier to prevent Bi from being in contact with the semiconductor chip package 140 by the diffusion and cracks from being generated. As an embodiment, the barrier layer 260 may include or be formed of nickel (Ni). As an embodiment, the thickness of the barrier layer 260 may be about 0.5 um.

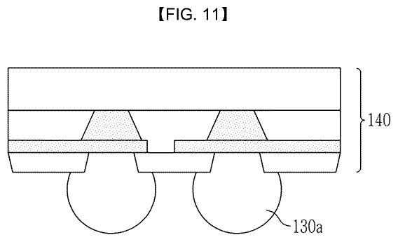

FIG. 11 to FIG. 14 relate to a method of forming a solder ball 130a of a semiconductor chip package 140 with a coined second connection members 130 to improve reliability, e.g., in the board level reliability evaluation (BLR). For convenience, FIG. 11 to FIG. 14 shows only components adjacent to the second connection members 130 in the semiconductor chip package 140, and some components are omitted. For example, the omitted components may be the same as any one of the other embodiments in the present disclosure.

FIG. 11 is a cross-sectional view showing a step of forming solder balls 130a on a semiconductor chip package 140 according to an embodiment.

Referring to FIG. 11, solder balls 130a are formed under a semiconductor chip package 140. In an embodiment, the solder balls 130a may include or be formed of a SAC solder alloy including tin (Sn), silver (Ag) and copper (Cu). The SAC solder alloy has a melting start temperature of about 217° C. and a bonding temperature of about 250° C. to 260° C.

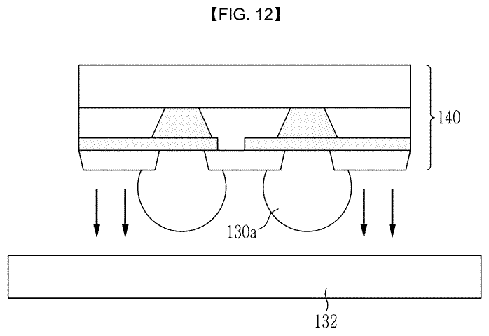

FIG. 12 is a cross-sectional view showing a step of preparing solder balls 130a for a coining according to an embodiment.

Referring to FIG. 12, a stainless steel (SUS) 132 is prepared to make bottom surfaces of the solder balls 130a flat. To proceed with the coining process, the semiconductor chip package 140 on which the solder balls 130a are formed is aligned on the stainless steel (SUS; 132).

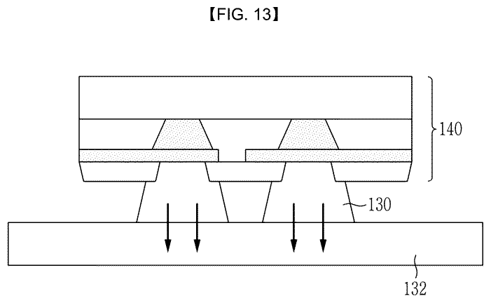

FIG. 13 is a cross-sectional view showing a step of forming coined second connection members 130 by coining solder balls 130a according to an embodiment.

Referring to FIG. 13, the bottom surface of the solder balls 130a formed in the semiconductor chip package 140 is in contact with the stainless steel (SUS; 132), and the solder balls 130a are simultaneously pressed with a press tool to form coined second connection members 130. During the coining process, as the bottom surfaces of a plurality of solder balls 130a are simultaneously pressed, the bottom surfaces of the plurality of second connection members 130 in contact with the stainless steel (SUS; 132) becomes flat and the second connection members 130 have a uniform height. For example, the bottom surfaces of the plurality of second connection members 130 may be on the same plane.

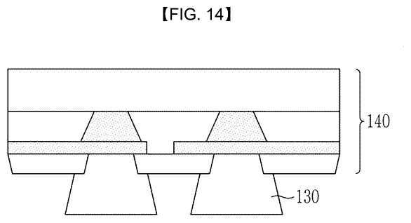

FIG. 14 is a cross-sectional view showing a step of completing a coined second connection members 130 according to an embodiment.

Referring to FIG. 14, the stainless steel 132 that is in contact with the bottom surfaces of a plurality of second connection members 130 is de-bonded. After this step, each second connection member of the plurality of second connection members 130 may include a flat bottom surface and a side surface inclined at a predetermined angle.

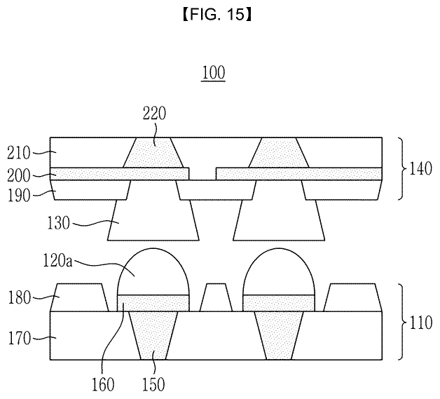

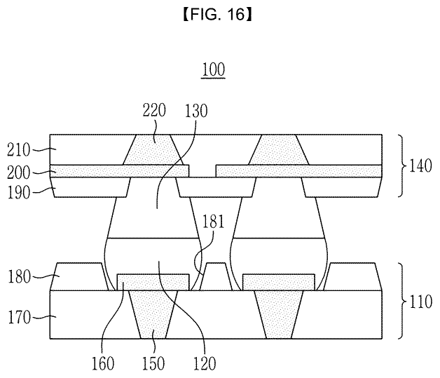

FIG. 15 is a cross-sectional view showing a step of aligning coined connection members 130 under a semiconductor chip package 140 and low temperature soldering pastes 120a on a printed circuit board 110 as one step among steps of a semiconductor package manufacturing method of an embodiment. For convenience, FIG. 15 and FIG. 16 shows only the components adjacent to the second connection members 130 in the semiconductor chip package 140 and the components adjacent to the low temperature soldering pastes 120a in the printed circuit board 110, and some components are omitted. For example, the omitted components may be the same as any one of the other embodiments in the present disclosure.

Referring to FIG. 15, the second connection members 130 under the semiconductor chip package 140 and the low temperature soldering pastes 120a on the printed circuit board 110 are aligned for the bonding.

FIG. 16 is a cross-sectional view showing a step of forming a semiconductor package 100 by bonding coined connection members 130 under a semiconductor chip package 140 and low temperature soldering pastes 120a on a printed circuit board 110 as one step among steps of a semiconductor package manufacturing method according to an embodiment.

Referring to FIG. 16, the coined second connection members 130 under the semiconductor chip package 140 and the low temperature soldering pastes 120a on the printed circuit board 110 are bonded. The melting start temperature of the low temperature soldering pastes 120a including SnBi is about 139° C., and the melting start temperature of the second connection members 130 including SAC is about 217° C. To improve the reliability of the bonding, the bonding process may be performed at a temperature of about 190° C. For example, a plurality of low temperature soldering pastes 120a are heated to a reflow peak temperature of 190° C. and maintained at 190° C. for 60 seconds. When the heat treatment is performed at the temperature of about 190° C., the coined second connection members 130 whose melting start temperature is about 217° C. do not melt, and only the low temperature soldering paste 120a whose melting start temperature is about 139° C. melts. The molten low temperature soldering paste 120a flows along the flat bottom surface of the second connection members 130, and the bonding is performed between the low temperature soldering paste 120a and the second connection members 130 in a heat treatment process. After the heat treatment, the low temperature soldering paste 120a is hardened to become the first connection member 120.

Due to the Bi diffusion during the heat treatment step, an interface layer (not shown) may be formed between the upper surface of the first connection member 120 and the bottom surface of the second connection member 130 and may remain after the heat treatment. The interface layer may include or be formed of both SAC and SnBi. SAC and SnBi may each have a concentration gradient in the thickness direction from the first connection member 120 to the second connection member 130 within the interface layer. The first and second connection members 120 and 130 in the present disclosure are connectors electrically connecting the printed circuit board 110 and the semiconductor chip package 140. For example, the first connectors 120 may be solder paste patterns, and the second connectors 130 may be solder balls.

According to the present disclosure, due to the second connection member 130 having the flat top surface and the side surface whose diameter decreases in a direction receding from a bottom (e.g., a bottom surface) of the second connection member 130 to a top (e.g., a top surface) of the second connection member 130, the low temperature soldering paste 120a molten during heat treatment flows only on the flat bottom surface of the second connection member 130 and does not flow along the side surface of the second connection member 130. Therefore, it is possible to improve reliability, e.g., in the board level reliability evaluation (BLR) by preventing crack generation between the semiconductor chip package 140 and the second connection member 130.

Even though different figures illustrate variations of exemplary embodiments and different embodiments disclose different features from each other, these figures and embodiments are not necessarily intended to be mutually exclusive from each other. Rather, certain features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A semiconductor package comprising:
a first structure;
a second structure;
a plurality of first connection members including SnBi; and
a plurality of second connection members including SAC (Sn, Ag and Cu),
wherein each first connection member of the plurality of first connection members has a first surface and a second surface opposite each other, and the first surface of each first connection member of the plurality of first connection members is bonded to the first structure,
a third surface of each second connection member of a plurality of second connection members is bonded to a corresponding second surface of a respective first connection member, and for each second connection member, a fourth surface of the second connection member that is opposite the third surface of the second connection member is bonded to the second structure,
the third surface of each second connection member is flat, and
a diameter of each second connection member decreases in a direction receding from the third surface of each second connection member.

2. The semiconductor package of claim 1, wherein an angle between a bottom surface of the second structure and a side surface of the second connection member is 60° to 80°.

3. The semiconductor package of claim 1, further comprising an under-bump structure between the second connection member and the second structure.

4. The semiconductor package of claim 1, further comprising an oxide layer on a side surface of the second connection member.

5. The semiconductor package of claim 4, wherein the oxide layer includes at least one of: Sn oxide, Ag oxide and Cu oxide.

6. The semiconductor package of claim 4, wherein the oxide layer has a height greater than 30% of a sum of heights of the first connection member and the second connection member.

7. The semiconductor package of claim 1, further comprising a barrier layer surrounding the third surface and a side surface of the second connection member.

8. The semiconductor package of claim 7, wherein the barrier layer includes nickel (Ni).

9. The semiconductor package of claim 1, further comprising an interface layer between the second surface of the first connection member and the third surface of the second connection member, wherein the interface layer includes SnBi and SAC.

10. The semiconductor package of claim 1, wherein a volume ratio of the first connection member to the second connection member is 0.4:1 to 0.5:1.

11. A semiconductor package comprising:
a first structure including:
a plurality of first vias;
a plurality of first metal pads on the plurality of first vias;
a first insulation layer surrounding the plurality of first vias; and
a second insulation layer disposed on the first insulation layer and including a plurality of openings;
a second structure including:
a third insulation layer;
a plurality of second metal pads on the third insulation layer;
a plurality of second vias on the plurality of second metal pads; and
a fourth insulation layer surrounding the plurality of second metal pads and the plurality of second vias;
a plurality of first connection members including SnBi; and
a plurality of second connection members including SAC (Sn, Ag and Cu),
wherein a first surface of each first connection member of the plurality of first connection members is bonded to a corresponding first metal pad of the plurality of first metal pads through a corresponding opening of the plurality of openings,
each second connection member of the plurality of second connection members penetrates the third insulation layer, for each first connection member, a second surface of the first connection member opposite the first surface of the first connection member is bonded to a third surface of a corresponding one of the plurality of second connection members, and for each second connection member of the plurality of second connection members, a fourth surface opposite the third surface of the is bonded to a corresponding second metal pad of the plurality of second metal pads,
the third surface of each second connection member of the plurality of second connection members is flat, and
a diameter in a horizontal direction of each second connection member of the plurality of second connection members decreases in a direction receding from the third surface.

12. The semiconductor package of claim 11, wherein each of the plurality of first metal pads is disposed within a corresponding opening of the plurality of openings and is spaced apart from an inner side surface of the opening.

13. The semiconductor package of claim 11, wherein each second connection member of the plurality of second connection members is in contact with the third insulation layer.

14. The semiconductor package of claim 11, wherein a contact angle between an interface between the first connection member and the second connection member and a side surface of the second connection member is 100° to 120°.

15. The semiconductor package of claim 11, wherein each first connection member of the plurality of first connection members contacts an upper surface and a side surface of a corresponding one of the plurality of first metal pads.

16. The semiconductor package of claim 11, further comprising an oxide layer on a side surface of each second connection member of the plurality of second connection members,
wherein a lowermost level of the oxide layer is lower than a height of 70% of a distance between the first metal pad and the second metal pad from the first metal pad.

17. A semiconductor package manufacturing method comprising:
forming a first package including a plurality of connection members including SAC (Sn, Ag and Cu);
pressing the first package to coin the plurality of connection members, wherein each coined connection member of the plurality of coined connection members has a diameter in a horizontal direction decreasing in a direction receding from a bottom of the connection member;
forming a second package including a plurality of soldering pastes including SnBi; and
bonding the plurality of coined connection members and the plurality of soldering pastes respectively under a predetermined temperature.

18. The semiconductor package manufacturing method of claim 17, wherein a melting point of the plurality of connection members is higher than the predetermined temperature.

19. The semiconductor package manufacturing method of claim 17, wherein a melting point of the plurality of soldering pastes is lower than the predetermined temperature.

20. The semiconductor package manufacturing method of claim 17, wherein:
the bonding the plurality of coined connection members and the plurality of soldering pastes respectively under the predetermined temperature includes heating the plurality of soldering pastes to a reflow peak temperature of 190° C. and maintaining the temperature at 190° C. for 60 seconds.
